(19) United States
(12) Patent Application Publication
(10) Pub. No.: US 2007/0228496 A1
(43) Pub. Date: Oct. 4, 2007

(54) Vertical Semiconductor Devices and Methods of Manufacturing Such Devices

(75) Inventors: Christelle Rochefort, Crolles (FR); Erwin A. Hijzen, Blanden (BE); Phillippe Meunier-Beillard, Bertem (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/574,334

(22) PCT Filed: Sep. 1, 2005
(86) PCT No.: PCT/IB05/52873

§ 371 Date: Feb. 27, 2007

(30) Foreign Application Priority Data
Sep. 3, 2004 (EP) 0419558.2

(51) Int. Cl. H01L 29/78

(52) U.S. Cl. 257/409; 438/269; 257/E29.262; 257/E21.41

(57) ABSTRACT

A vertical semiconductor device, for example a trench-gate MOSFET power transistor (1), has a drift region (12) of one conductivity type containing spaced vertical columns (30) of the opposite conductivity type for charge compensation increase of the device breakdown voltage. Insulating material (31) is provided on the sidewalls only of trenches (20) in the drift region (12) and the opposite conductivity type material is epitaxially grown from the bottom of the trenches (20). The presence of the sidewall insulating material (31) reduces the possibility of defects during the epitaxial growth and hence excessive leakage currents in the device (1). The insulating material (31) also prevents epitaxial growth on the trench sidewalls and hence substantially prevents forming voids in the trenches which would lessen the accuracy of charge compensation. The epitaxial growth by this method can be well controlled and may be stopped at an upper level (21) below the top major surface (10a). Thus, for example, trench-gates 22, 23 may be formed in the same trenches (20) above the compensation columns (30).

This invention relates to vertical semiconductor devices and methods of manufacturing such devices.

In particular, this invention relates to a semiconductor device arranged for forward current flow in a vertical direction between top and bottom major surfaces of the device, wherein the device has a drift region consisting of material of one conductivity type. Such a device which is of particular interest in relation to this invention is a vertical insulated gate field effect power transistor in which the drift region is a drain drift region, although the invention is applicable to other vertical semiconductor devices such as bipolar transistors and diodes. The reverse breakdown voltage of these devices conventionally can be increased by reducing the dopant concentration and increasing the size of the drift region. However, this also increases the on-resistance of the device in proportion to approximately the square of the desired reverse breakdown voltage.

It is known for this problem to be addressed in vertical insulated gate field effect power transistors by having the drain drift region contain spaced vertical columns of material of the opposite conductivity type which provide charge compensation to increase the reverse breakdown voltage of the transistor. That is to say that for a given doping level of the forward current drain drift material of one conductivity type, the space charge per unit area in that material when the transistor is reverse biased is substantially compensated, or balanced, by the space charge per unit area in the columns of material of the opposite conductivity type and the breakdown voltage is higher than that for a conventional transistor without the columns of opposite conductivity type. Also this means that, for a given desired breakdown voltage of the transistor, the doping level of the one conductivity type material can be higher for a given depth of the drain drift region, and hence the on-resistance of the transistor can be lower than for a conventional transistor. Increasing the breakdown voltage by increasing the depth of the drain drift region in these charge compensation/balance transistors increases the on-resistance in linear proportion instead of in square proportion.

An early disclosure of this type of charge compensation/charge balance transistor with explanations of its properties corresponding to those given above is found in U.S. Pat. No. 4,754,310 (our reference PHB32740). In this U.S. patent it is suggested that the charge balance structure can be formed by etching trenches in the one conductivity type drain drift region and then epitaxially depositing material of the opposite conductivity type to fill these trenches.

A more recent disclosure of this type of charge compensation power transistor, now also known as a superjunction (SJ) device or multi-RESURF device, is in an article by G. Deboy, et al., Proc. IEDM, pp 683-685 (1998). This suggests forming the charge compensation columns of opposite conductivity type using a multi-epitaxial growth and implantation process, that is the alternating deposition of n-doped epitaxial layers and implantation of p-islands. If the number of epitaxial steps is not to be too high and costly, then merging the p-islands requires a high thermal budget with lateral diffusion which means a high pitch size, thus limiting the application of these transistors to a higher voltage range (above around 400 volts).

More recently still there have been proposals which revert to the suggestion in U.S. Pat. No. 4,754,310 for forming the opposite conductivity type columns by epitaxially filling etched trenches. The trenches for the opposite conductivity type columns should be deep, that is extending through most or all of the depth of the drain drift region, in order to provide good charge compensation. These trenches should also be narrow, in order to take up as small an area of the device as possible and also in order to have as small a pitch size as possible. A smaller pitch size enables charge compensation to be obtained with a higher doping concentration of the drift region, resulting in a lower on-resistance of the device. Also, a smaller pitch size with higher doping concentration of the drift region enables devices to be made with charge compensation which may be in a lower breakdown voltage range (down to a lower limit of approximately 20 volts).

The problems with this method of epitaxial filling of deep and narrow (high aspect ratio) trenches for charge compensation columns are how to achieve defect-less filling and how to achieve void-less filling. The mentioned defects are in the etched trench surfaces and thus are at the boundaries between the two conductivity type materials as well as extending into the epitaxial filling material. These defects can allow excessive leakage currents. The mentioned voids are caused by epitaxial growth from the bottom of the trench being accompanied by simultaneous growth from the sidewalls of the trench, this sidewall growth meeting at the top of the trench before the trench is filled. These voids can lessen the accuracy of the charge balance. Also, once a void is present it might be opened during subsequent etching process steps and perhaps, for example, be filled with conducting material which will detract from the charge balance. Furthermore, we have found by experiment that small variations in the shape of a trench can have a large influence on the position in the trench of a void produced by growth from the sidewalls of the trench. So the position of these voids in the trenches can change between different locations on a single wafer, which may give reproducibility problems. An article by S. Yamauchi, et al., ISPSD, pp 133-136 [2002] proposes a complex multi-stage process involving pre-H₂-annealing the trenches to reduce defects, a first epitaxial growth, HCL etching to open the top of the trench where the first growth has formed a void, a second epitaxial growth to fill the void, and post-H₂-annealing. The multiple steps in this process require a high thermal budget, which restricts attainable doping profiles and cell pitch. An article by M. Rub, et al., ISPSD, pp 203-206 [2003] proposes a structure in which trenches contain both a first n-type epitaxial thin layer and a second p-type epitaxial thin layer so that the charge compensation is locally defined in each trench. This alternative structure is recommended because it is said that experiments show that void free epitaxial filling of etched trenches is not homogenously distributed across a wafer. We consider that for this structure, if the epitaxial growth rate of the thin layers is not uniform then the charge compensation will be significantly affected.

According to a first aspect of the present invention there is provided a method of manufacturing a semiconductor device arranged for forward current flow in a vertical direction between top and bottom major surfaces of the device, wherein the device has a drift region consisting of material of one conductivity type and wherein the drift region contains spaced vertical columns of material of the opposite conductivity type which provide charge compensation to increase the reverse breakdown voltage of the device, the method including etching vertical trenches from said top major surface into the drift region material of one conductivity type and then providing material in the trenches for the spaced columns of the opposite conductivity type; wherein the method includes providing insulating material on the sidewalls of the etched trenches and then epitaxially growing material of the opposite conductivity type from the bottom towards the top of the trenches.

The presence of the insulating material on the trench sidewalls prevents any defects in the material of opposite conductivity type crossing into the drain drift material of the one conductivity type, which therefore prevents excessive leakage currents.

Because epitaxial growth inside the trenches takes place in the above-defined method of the invention from the bottom towards the top, and not on the sidewalls of the trenches where the insulating material is present, the above-mentioned problem of how to achieve void-less filling is substantially solved. Also, because this method of filling is less sensitive to the exact shape of the trench, we consider that this void-less filling should be achieved substantially across a full wafer, thus providing a higher yield of acceptable transistors.

The above-defined method of the invention is less complex than that proposed in Yamauchi article and will not require such a high thermal budget. Also, an advantage of the above-defined method of the invention compared with that proposed in the Rub article is that if the epitaxial growth rate is not uniform, then excess material may be grown and then removed (for example using chemical-mechanical polishing).

An application of the method of the invention which is of particular interest is where the device is a vertical insulated gate field effect power transistor and the drift region is a drain drift region.

The extent of epitaxial growth from the bottom towards the top of the trenches in accordance with the invention can be well controlled which can simplify further processing steps in the manufacture of the transistor. Thus, in a preferred method in accordance with the invention wherein the transistor is a vertical trench-gate MOSFET, the epitaxial growth of the opposite conductivity type material in the trenches may be stopped at an upper level below the top of the trenches, the insulating material then being removed from the trench sidewalls above said upper level, gate insulating material and gate conductive material then being provided in the trenches above said upper level, and channel accommodating regions and source regions being provided above said upper level. Preferably, the channel accommodating regions and source regions are provided after the gate insulating and gate conductive materials are provided.

In another preferred application of the method of the invention to a vertical insulated gate field effect power transistor, the transistor is a vertical planar gate MOSFET, planar gates are provided on said top major surface adjacent the drain drift material of said one conductivity type and adjacent channel accommodating regions and source regions, the epitaxially grown material is provided in the trenches at a conductivity required for charge compensation up to the level of the junction between the drain drift region and the channel accommodating region adjacent the trenches, and material having a higher conductivity is provided in the trenches from that level up to the top major surface. The epitaxial growth in the trenches of the opposite conductivity type material suitable for charge compensation may be continued to the top major surface, and the epitaxially grown material in the trenches above said junction level then converted to said higher conductivity. Alternatively the epitaxial growth in the trenches of the opposite conductivity type material suitable for charge compensation may be stopped at the junction level, and the trenches then filled to the top major surface with said material having a higher conductivity. In this case said insulating material may be removed from the trench sidewalls above the junction level before the trenches are filled to the top major surface. The channel accommodating regions and source regions are preferably provided after the planar gates by at least partial self-alignment to the planar gates.

According to a second aspect of the present invention there is provided a semiconductor device arranged for forward current flow in a vertical direction between top and bottom major surfaces of the device, wherein the device has a drift region consisting of material of one conductivity type and wherein the drift region contains spaced vertical columns of material of the opposite conductivity type which provide charge compensation to increase the reverse breakdown voltage of the device, wherein there are vertical trenches in the drift region material of one conductivity type, there is insulating material on the sidewalls of the trenches extending from the bottom of the trenches, and there is epitaxial material filling the area of the trenches within said insulating material, the epitaxial material providing the spaced columns of the opposite conductivity type. The insulating material on the trench sidewalls isolates any defects in the epitaxial material of opposite conductivity type from the drain drift material of one conductivity type, which therefore prevents any excessive leakage currents.

In a preferred application of this aspect of the invention, the device is a vertical insulated gate field effect power transistor and the drift region is a drain drift region. One such transistor may be vertical trench-gate MOSFET, wherein the insulating material on the sidewalls of the trenches and the epitaxial material filling the area within the insulating material both extend to an upper level below said top major surface, wherein gate insulating material and gate conductive material are in the trenches above said upper level, and wherein channel accommodating regions and source regions are above said upper level. Another such transistor may be a vertical planar gate MOSFET, wherein planar gates are provided on said top major surface adjacent the drain drift material of said one conductivity type and adjacent channel accommodating regions and source regions, and wherein the epitaxial material is in the trenches at a conductivity required for charge compensation up to the level of the junction between the drain drift region and the channel accommodating regions adjacent the trenches, and wherein material having a higher conductivity is in the trenches from that level up to the top major surface. In this planar gate transistor the insulating material on the trench sidewalls may extend only up to the junction level.

Selective epitaxial growth from the bottom to the top of trenches having insulating material on the trench sidewalls is already known per se in the semiconductor art for applications other than charge compensation columns in the drift region of vertical devices. U.S. Pat. No. 5,384,280 (Toshiba) is concerned with forming isolation trenches between different integrated circuits, e.g. DRAMs, in a semiconductor body where these isolation trenches are of different widths, e.g. 0.2 micron wide and 1.0 micron wide trenches each being 0.5 micron deep. It is proposed to provide oxide-nitride sidewalls in such trenches and then selectively grow epitaxial silicon in the trenches. The oxide-nitride sidewalls provide the required isolation between the integrated circuits outside the trenches, while the epitaxial silicon within the trenches does not stress the rest of the silicon substrate. U.S. Pat. No. 6,555,891 (IBM) is concerned with BiCMOS devices and how to provide bipolar transistors extending deeper than the buried oxide layer of a SOI structure. It is proposed to etch a trench through the BOX layer, insulate the trench sidewalls with silicon oxide or nitride or oxide-nitride and epitaxially grow silicon within the trench. The trench may have a width ranging from microns to millimetres depending on the devices, e.g. DRAM cells, which are formed within the trench, these devices being insulated at the trench sidewalls from FETs formed in the SOI outside the trench.

Embodiments of vertical semiconductor devices and methods of making these devices in accordance with the present invention will now be described, by way of example, with reference to the accompanying diagrammatic drawings, in which:

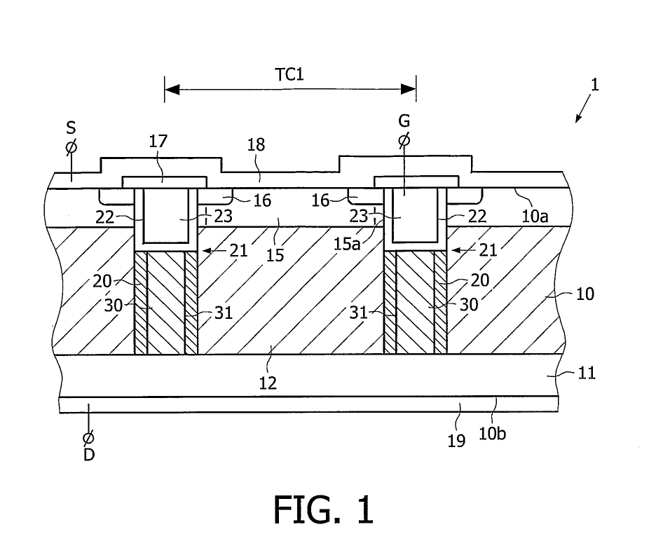

FIG. 1 shows a diagrammatic cross-sectional view through part of a vertical insulated gate field effect power transistor in the form of a trench-gate MOSFET in accordance with the present invention;

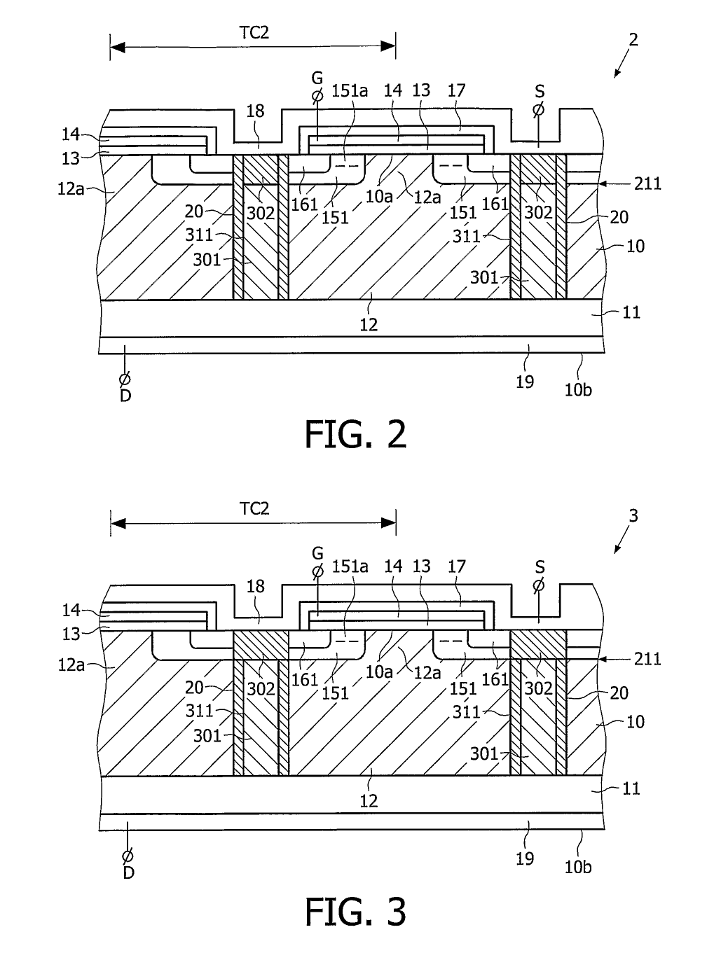

FIG. 2 shows a diagrammatic cross-sectional view through part of a vertical insulated gate field effect power transistor in the form of a planar gate MOSFET in accordance with the present invention;

FIG. 3 shows a diagrammatic cross-sectional view through part of another vertical insulated gate field effect power transistor in the form of a planar gate MOSFET in accorance with the present invention;

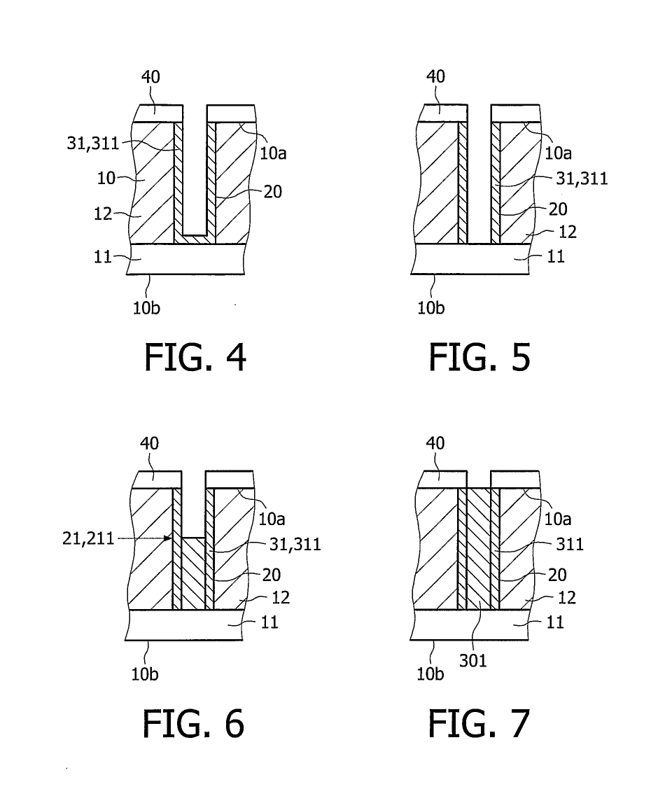

FIGS. 4 and 5 show steps in a method, in accordance with the present invention, of manufacturing a vertical insulated gate field effect power transistor, these steps being common to making the transistors of FIGS. 1, 2 and 3;

FIG. 6 shows a step, further to those shown in FIGS. 4 and 5, in a method of making the transistors of FIGS. 1 and 3; and

FIG. 7 shows a step, further to those shown in FIGS. 4 and 5, in a method of making the FIG. 2 transistor.

Referring now to FIG. 1, there is shown a trench-gate MOSFET form of vertical insulated gate field effect power transistor semiconductor device 1. The device 1 comprises a monocrystalline silicon semiconductor body 10 and is arranged for forward current flow in a vertical direction between top and bottom major surfaces 10a, 10b of the device body 10. The body 10 has a substrate drain region 11 of one conductivity type (n+) and a drain drift region 12 of the one conductivity type (n). The drift region 12 contains spaced vertical columns 30 of material of the opposite conductivity type (p) at a conductivity required for charge compensation to increase the reverse breakdown voltage of the device 1. There are vertical trenches 20 in the drift region material 12, and these trenches 20 extend between the drain substrate 11 and the top major surface 10a. Insulating material 31 on the sidewalls of the trenches 20 extends from the bottom of the trenches 20 and epitaxial material fills the area within the insulating material 31 and provides the spaced columns 30 of the opposite conductivity type. The insulating material 31 and the epitaxial material 30 both extend to an upper level 21 below the top major surface 10a. Gate insulating material 22 and gate conductive material, preferably highly doped polycrystalline silicon, 23 are in the trenches 20 above the upper level 21 and p-type channel accommodating regions 15 and n-type source regions 16 are above the upper level 21.

The device 1 has a large number of electrically parallel transistor cells sharing the common drain region 11. FIG. 1 shows the lateral extent (cell pitch) TC1 of one transistor cell with two sections of a peripheral trench-gate 22, 23 for that cell. When a suitable gate potential is applied to the gate conductive material 23 in the on-state on the device 1, a vertical conduction channel 15a is formed in the p-type region 15 within each cell adjacent the trench-gate, whereby forward current flows in each transistor cell TC1 from the annular source region 16 through the conduction channel 15a and vertically through the drift region 12 to the drain region 11. Insulating regions 17 are provided over the trench-gates 22, 23. Source metallisation 18 is provided over the insulating regions 17. Electrical connection (not shown) to the gates 23 is provided outside the area of the transistor cells. Drain metallisation 19 is provided under the drain substrate 11.

The function and advantages of the p-type charge compensation columns 30 for the reverse breakdown voltage and the on-resistance of the transistor 1 have been explained above in relation to the prior art. In the device 1, the insulating material 31 on the sidewalls of the trenches 20 isolates any defects in the p-type epitaxial material 30 from the n-type drain drift material 12, which therefore presents any excessive leakage currents. The junction of the channel accommodating region 15 and the drift region 12 must be adjacent the trench gate a little above the top of the charge compensation column 30. The top of the material 30 is connected to the source electrical connection (not shown) which enhances the RESURF effect.

Referring now to FIG. 2, there is shown a planar gate MOSFET form of vertical insulated gate field effect power transistor semiconductor device 2. The device 2 comprises a semiconductor body 10 with top and bottom major surfaces 10a, 10b, a substrate drain region 11 of one conductivity type (n+) and a drain drift region 12 of the one conductivity type (n) in like manner to the device 1 of FIG. 1, except that the drift region 12 extends to the top surface 10a. There are vertical trenches 20 in the drift region material 12, and these trenches 20 extend between the drain substrate 11 and the top surface 10a. Insulating material 311 on the sidewalls of the trenches 20 extends from the bottom of the trenches 20 and epitaxial material of opposite conductivity type (p) at a conductivity required for charge compensation fills the area within the insulating material 311 up to the level 211 of the junction between the drain drift region 12 and the channel accommodating regions 151 adjacent the trenches 20 and provides spaced vertical charge compensation columns 301 contained in the drift region 12 in like manner to the device 1 of FIG. 1. Material 302 having a higher conductivity than the charge compensation material 301 is in the trenches 20 within the insulating material 311 from the level 211 up to the top major surface 10a. The material 302 can be epitaxial silicon, or polycrystalline silicon, which is more highly doped than the material 301.

The device 2 has a large number of electrically parallel transistor cells sharing the common drain region 11. FIG. 2 shows the lateral extent (cell pitch) TC2 of one transistor cell with a peripheral planar gate structure 13, 14 for that cell TC2 and for an adjacent cell. Each planar gate structure has a planar gate insulating layer 13 on the top major surface 10a with gate conductive material 14 thereon.

The drain drift region 11 extends to the top major surface 10a at a peripheral region 12a of adjacent transistor cells. Within the peripheral drain drift region 12a of each transistor cell, and to either side of a charge compensation column 301, there is a p-type channel accommodating region 151 and an n-type source region 161. Thus the planar gates 13, 14 on the surface 10a are adjacent the drain drift material 12 and adjacent channel accommodating regions 151 and source regions 161. When a suitable gate potential is applied to the gate conductive material 14 in the on-state of the device 2, a lateral conduction channel 151a is formed in the p-type region 151 adjacent the planar gate 13, 14 whereby forward current flows within each cell TC2 from the source region 161 laterally through the conduction channel 151a into the peripheral drain drift region 12a and then vertically through the drain drift regions 12a and 12 to the substrate drain region 11. Insulating regions 17 over the planar gates 13, 14, source metallisation 18, electrical connection (not shown) to the gate conductive material 14 and drain metallisation 19 are provided in like manner to the device 1 of FIG. 1.

Referring now to FIG. 3, there is shown a planar gate MOSFET power transistor 3 which differs from the transistor 2 shown in FIG. 2 in that the insulating material 311 on the sidewalls of the trench 20 extends only up to the junction level 211.

In the device 3 of FIG. 3 the material 302 is directly connected to the sides of the source 161 and channel accommodating 151 regions. An advantage of this is that the source metallisation 18 could be connected to the regions 161 and 151 only via the material 302 at the top major surface 10a; that is to say that the trenches 20 could be next to the insulating material 17 over the gates 14, so that the gates 14 could be closer together and the pitch size could be smaller compared with the device 2 of FIG. 2.

The function and advantages of the p-type charge compensation columns 301 with the insulation 311 on the sidewalls of the trenches 20 are substantially the same for the devices 2 and 3 of FIGS. 2 and 3 as are stated above for the columns 30 and sidewall insulation 31 of the device 1 of FIG. 1.

The reason for having the higher conductivity material 302 in the trenches 20 above the level 211 of the junction between the channel accommodating regions 151 and the drift region 12 adjacent the trenches 20 in the planar gate MOSFET devices 2 and 3 of FIGS. 2 and 3 is to enhance the RESURF effect, that is the increase in reverse breakdown voltage of the devices provided by the charge compensation columns. For ideal charge compensation the potential at the top of the charge compensation columns 301 should be the same as the potential at the level 211 of the junction between the channel accommodating regions 151 and the drift region 12. In this connection, U.S. Pat. No. 6,605,862 (our reference PHNL 010137) describes RESURF devices having trenched field-shaping regions provided by a resistive path of semi-insulating material and it is explained how the electric field distribution in the drain drift region for increased breakdown voltage is improved if the start of the potential drop along the resistive path is closely aligned with the depth of the junction between the channel accommodating regions and the drain drift region. In the case of the present invention using charge compensation columns for the RESURF effect, although for medium and high voltage devices, above about 100 volts and up to about 600 volts, the voltage drop between the channel accommodating 151 and drain 11 regions occurs through a deep drift region 12 up to about 30 micron depth, having only a small voltage drop in the trenches 20 from the source metallisation 18 to the level 211 will still be of advantage in helping equalise the potential in the trench at the level 211 with that at the top of the drift region 12. This small voltage drop is achieved by the higher conductivity material 302. In low voltage devices, below about 100 volts, the voltage drop between the channel accommodating 151 and drain 11 regions occurs through a comparatively shallow drift region 12, down to about 1 micron depth for 20 volts, and it becomes particularly important to have only a small voltage drop, that is a small proportion of the voltage drop in the drift region 12, occurring in the trenches 20 from the source metallisation 18 to the level 211 in order to equalise the potential in the trench at the level 211 with that at the top of the drift region 12 and therefore it is particularly important to have the higher conductivity material 302. To have optimal RESURF the dopant dose in the drift region 12 and the charge compensation column 301 should be around 1 e12 cm⁻². The doping concentration of the region 302 should be as high as possible to limit the voltage drop in this material, for example around 1 e20 cm⁻³.

Possible variations in the configuration of the charge compensation columns within the scope of the present invention include the following. The configuration of the trench-gate MOSFET device 1 FIG. 1 is advantageous for a smaller cell pitch in lower voltage, for example below 100 volts, transistors, However, for larger cell-pitch trench-gate MOSFETs the trench-gate device 1 may have the charge compensation columns 30, 31 in the central region of the transistor cell TC1 instead of being under the trench-gates 22, 23. Such central region charge compensation columns in larger cell-pitch trench-gate MOSFETs may extend up to the top surface 10a although, particularly for lower voltage trench-gate MOSFETs, it would be advantageous for these central region charge compensation columns to extend in the trenches up to the level of the junction between the drain drift region 12 and the channel accommodating regions 15 with higher conductivity material provided in the trenches 20 from that level up to the top major surface 10a in the same manner as shown for the charge compensation columns 301 with upper region higher conductivity material 302 in the planar gate MOSFETs 2 and 3 of FIGS. 2 and 3. For the planar gate MOSFETs of FIGS. 2 and 3 the upper region higher conductivity material 302 could be omitted, particularly for higher voltage devices, within the scope of the present invention.

Referring now to FIGS. 4 and 5, there are shown steps in a method in accordance with the invention, these steps being common to making the FIG. 1 trench-gate transistor and the FIGS. 2 and 3 planar gate transistors. Initially a monocrystalline silicon semiconductor body 10 is provided consisting of an n+ conductivity type substrate 11 for forming the drain region and an n conductivity type epitaxial layer 12 is grown on the substrate 11 for forming the drain drift region. The top of the layer 12 will form the top major surface 10a of the transistor and the bottom of the substrate 11 will form the bottom major surface 10b of the transistor. A thick hard mask 40, for example silicon oxide, is provided on the top surface 10a and windows provided by this mask are used to anisotropically etch deep vertical trenches 20 from the top surface 10a into the drift region material 12. The trenches 20 preferably extend through the whole depth of the layer 12 down to the substrate 11. In an experiment, we have etched such trenches 1.5 micron wide and 12 micron deep. These trenches 20 will be approximately 1 micron deep for each 20 volts of the required reverse breakdown voltage of the transistor, that is up to about 30 micron deep for a 600 volts device. A thin, for example 40 nm, layer 31, 311 of insulating material is then provided inside the trenches 20 on the trench bottom and sidewalls, for example by deposition or growth of silicon oxide as shown in FIG. 4. Anisotropic dry oxide etching is then performed to remove the oxide at the trench bottoms leaving the oxide insulating material 31, 311 provided only on the sidewalls of the etched trenches 20 as shown in FIG. 5. P conductivity type material 30, 301 is then epitaxially grown from the bottom towards the top of the trenches 20 as shown in FIGS. 6 and 7.

In an experiment, we cleaned the semiconductor body as shown in FIG. 5 followed by an in-situ bake at 1050° C. in order to remove the natural oxide on the body. The epitaxial growth was then done at a temperature of 1050° C. and total pressure of 40 Torr using TCS (trichlorosilane) as a silicon gas precursor with hydrogen as a precursor gas. A high growth rate of greater than one micron per minute and good selectivity to oxide, that is to say substantially no epitaxial silicon growth on the sidewall layers 31, 311, was obtained without process optimisation. The deposition time for filling the 12 micron trenches mentioned above was about 5 minutes. The sidewall insulating material prevents any defects in the charge compensation columns crossing into the drain drift material which therefore prevents any leakage currents from being excessive.

Because epitaxial growth inside the trenches takes place from the bottom towards the top, and not on the sidewalls of the trenches where the insulating material is present, substantially void-less filling of the trenches is achieved. Also, because this method of filling is less sensitive to the exact shape of the trench, we consider that this void-less filling should be achieved substantially across a full wafer, thus provided a higher yield of acceptable transistors.

The silicon level height inside the trenches can be well controlled by adapting the silicon growth time during the epitaxy process in the above-described method in accordance with the present invention. This can simplify further processing in manufacture of the semiconductor devices.

FIG. 6 shows that, for the trench-gate MOSFET device 1 of FIG. 1 and for the planar gate MOSFET devices 2 and 3 of FIGS. 2 and 3, the epitaxial growth of the p conductivity type material 30, 301 is stopped at an upper level 21, 211 below the top of the trenches 20.

The next step in making the device 1 of FIG. 1 is to remove the sidewall insulating material 31 from the trench sidewalls above the upper level 21. Gate insulating material 22 as shown in FIG. 1 is then provided, by growth of silicon oxide, in the trenches 20 above the upper level 21 and gate conductive material 23 is then provided, after removal of the hardmask 40, by deposition of doped polycrystalline silicon and planarised to the top major surface 10a. The channel accommodating regions 15 and source regions 16 as shown in FIG. 1 are preferably provided by implantation and annealing after the gate insulating and gate conductive materials 22, 23 are provided. This is preferred because the channel accommodating regions and source regions can be easily adjusted to the required depth compared to the trench-gate depth with advantages for the thermal budget. Alternatively, the channel accommodating regions and perhaps also the source regions can be formed before etching the trenches 20 and the upper level 21 of the epitaxial growth can then be adjusted to provide the trench-gates at the required depth compared to the channel accommodating regions. The device 1 is then completed by providing the insulating regions 17 over the trench-gates 22, 23 and then providing the source metallisation 18, gate metallisation (not shown) and drain metallisation 19.

For the device 2 of FIG. 2, after stopping the epitaxial growth of the material 301 at the level 211, the sidewall insulation 311 remains in place and the trenches 20 are filled with the higher conductivity material 302. This filling may be by further epitaxial growth of more highly doped silicon, or by deposition of more highly doped material which may be polycrystalline silicon. Then, after removal of the hard mask 40, steps in making the device 2 of FIG. 2 are as follows. Gate insulating material is provided as a layer on the top surface 10a, by growth of silicon oxide, a layer of gate conductive material is then deposited as doped polycrystalline silicon, and these two layers are then patterned to provide the planar gates 13, 14. The channel accommodating regions 151 and source regions 161 are provided by implantation and annealing, preferably after forming the planar gates 13, 14 and furthermore preferably by at least partial self-alignment to the planar gates. The device 2 is then completed by providing the insulating regions 17 over the planar gates 13, 14 and then providing the source metallisation 18, gate metallisation (not shown) and drain metallisation 19.

FIG. 7 shows that, for the planar gate MOSFET device 2 of FIG. 2, the epitaxial growth of the p conductivity type material 301 may be continued to the top of the trenches 20. The material 301 above the level 211 is then converted to the higher conductivity material 302 by implantation.

For the planar gate MOSFET device 3 of FIG. 3, the sidewall insulation 311 is removed above the level 211 after stopping the epitaxial growth of the material 301 at the level 211 as shown in FIG. 6. After removal of the hardmask 40, the upper part of the trenches 20 is then filled with the higher conductivity material 302. This filling step may be by deposition, for example of polycrystalline silicon; or it may be by epitaxial growth, for example of boron doped silicon, on top of the material 301 and on the sides of the trenches 20. The device 3 is then completed in the same manner as has been described for the device 2 of FIG. 2.

1. A method of manufacturing a semiconductor device arranged for forward current flow in a vertical direction between top and bottom major surfaces of the device, wherein the device has a drift region consisting of material of one conductivity type and wherein the drift region contains spaced vertical columns of material of the opposite conductivity type which provide charge compensation to increase the reverse breakdown voltage of the device, the method including etching vertical trenches from said top major surface into the drift region material of one conductivity type and then providing material in the trenches for the spaced columns of the opposite conductivity type; wherein the method includes providing insulating material on the sidewalls of the etched trenches and then epitaxially growing material of the opposite conductivity type from the bottom towards the top of the trenches.

2. A method as claimed in claim 1, wherein the device is a vertical insulated gate field effect power transistor and the drift region is a drain drift region.

3. A method as claimed in claim 2, wherein the transistor is a vertical trench-gate MOSFET, wherein the epitaxial growth of the opposite conductivity type material in the trenches is stopped at an upper level below the top of the trenches, the insulating material then being removed from the trench sidewalls above said upper level, and wherein gate insulating material and gate conductive material are then provided in the trenches above said upper level, and wherein channel accommodating regions and source regions are provided above said upper level.

4. A method as claimed in claim 3, wherein the channel accommodating regions and source regions are provided after the gate insulating and gate conductive materials are provided.

5. A method as claimed in claim 2, wherein the transistor is a vertical planar gate MOSFET, wherein planar gates are provided on said top major surface adjacent the drain drift material of said one conductivity type and adjacent channel accommodating regions and source regions (161), wherein the epitaxially grown material is provided in the trenches at a conductivity required for charge compensation up to the level of the junction between the drain drift region and the channel accommodating regions adjacent the trenches, and wherein material having a higher conductivity is provided in the trenches from that level up to the top major surface.

6. A method as claimed in claim 5, wherein the epitaxial growth in the trenches of the opposite conductivity type material suitable for charge compensation is continued to the top major surface, and wherein the epitaxially grown material in the trenches above said junction level is then converted to said higher conductivity material.

7. A method as claimed in claim 5, wherein the epitaxial growth in the trenches of the opposite conductivity type material suitable for charge compensation is stopped at the junction level, and wherein the trenches are then filled to the top major surface with said material having a higher conductivity.

8. A method as claimed in claim 7, wherein said insulating material is removed from the trench sidewalls above the junction level before the trenches are filled to the top major surface.

9. A method as claimed in claim 4, wherein the channel accommodating regions and source regions are provided after the planar gates by at least partial self-alignment to the planar gates.

10. A semiconductor device made by the method as claimed in claim 1.

11. A semiconductor device arranged for forward current flow in a vertical direction between top and bottom major surfaces of the device, wherein the device has a drift region consisting of material of one conductivity type and wherein the drift region contains spaced vertical columns of material of the opposite conductivity type which provide charge compensation to increase the reverse breakdown voltage of the device, wherein there are vertical trenches in the drift region material of one conductivity type, there is insulating material on the sidewalls of the trenches extending from the bottom of the trenches and there is epitaxial material filling the area of the trenches within said insulating material, the epitaxial material providing the spaced columns of the opposite conductivity type.

12. A device as claimed in claim 11, wherein the device is a vertical insulated gate field effect power transistor and the drift region is a drain drift region.

13. A transistor as claimed in claim 12, wherein the transistor is a vertical trench-gate MOSFET, wherein the insulating material on the sidewalls of the trenches and the epitaxial material filling the area within the insulating material both extend to an upper level below said top major surface, wherein gate insulating material and gate conductive material are in the trenches above said upper level, and wherein channel accommodating regions and source regions are above said upper level.

14. A transistor as claimed in claim 12, wherein the transistor is a vertical planar gate MOSFET wherein planar gates are on said top major surface adjacent the drain drift material of said one conductivity type and adjacent channel accommodating regions and source regions and wherein the epitaxial material is in the trenches at the conductivity required for charge compensation up to the level of the junction between the drain drift region and the channel accommodating regions adjacent the trenches and wherein material having a higher conductivity is in the trenches from that level up to the top major surface.

15. A transistor as claimed in claim 14, wherein the insulating material on the trench sidewalls extends only up to the junction level.
